(19) United States
(12) Patent Application Publication
(10) Pub. No.: US 2026/0152853 A1
(43) Pub. Date: Jun. 4, 2026

(54) COMPOUND ORIFICE INLET NOZZLE FOR TUNING FLOW FROM GAS DISTRIBUTION SHOWERHEADS

(71) Applicant: Lam Research Corporation, Fremont, CA (US)

(72) Inventors: Damien M. Slevin, Salem, OR (US); Sean M. Donnelly, Portland, OR (US)

(73) Assignee: Lam Research Corporation, Fremont, CA (US)

(21) Appl. No.: 19/132,290

(22) PCT Filed: Oct. 27, 2023
(86) PCT No.: PCT/US2023/078111

§ 371 Date: May 22, 2025

Related U.S. Application Data
(60) Provisional application No. 63/387,932, filed on Dec. 16, 2022.

(51) Int. Cl. C23C 16/455; C23C 16/458

(52) U.S. Cl. CPC C23C 16/45565; C23C 16/45536; C23C 16/45544; C23C 16/458

(57) ABSTRACT

Described is a showerhead assembly comprising a faceplate and a plurality of orifices extending through the faceplate from an upstream side to an opposing downstream side. At least one orifice of the plurality of orifices comprises an entrance zone disposed on the upstream side of the faceplate. The entrance zone comprises a compound bore having at least a first sidewall stacked over a second sidewall. The first sidewall has a first subtended angle that is larger than a second subtended angle of the second sidewall.

### CLAIM FOR PRIORITY

This application claims priority to U.S. Provisional Patent Application No. 63/387,932, filed on Dec. 16, 2022, titled “COMPOUND ORIFICE INLET NOZZLE FOR TUNING FLOW FROM GAS DISTRIBUTION SHOWERHEADS,” and which is incorporated by reference in entirety.

### BACKGROUND

Process tools are used to perform treatments such as deposition and etching of film on semiconductor wafer substrates. These process tools can comprise a vacuum chamber in which chemical vapor deposition (CVD), including plasma-enhanced chemical vapor deposition (PECVD) and atomic layer deposition (ALD) processes can be performed. Precision deposition processes such as ALD use precise delivery of precursor gases and vapors (collectively, process gases) into the vacuum chamber through a gas distribution showerhead within the vacuum chamber. A showerhead may be engineered to deliver process gases in a particular flow distribution over the surface of a deposition substrate, such as a semiconductor wafer. The process gases may react with the substrate surface, producing solid thin films. In many applications, the showerhead may be engineered to produce films having uniform thickness profiles across the diameter of the substrate.

### BRIEF DESCRIPTION OF THE DRAWINGS

FIG. 1 illustrates a cross-sectional view of an exemplary process chamber, in accordance with at least one embodiment.

FIG. 2 illustrates a cut-away view of a showerhead, comprising orifices having simple entrance zones in accordance with at least one embodiment.

FIG. 3 illustrates a cut-away view of a showerhead comprising orifices having compound conical entrance zones, in accordance with at least one embodiment.

FIG. 4 illustrates a cross-sectional view of a faceplate, showing a section comprising a uniform distribution of orifices, in accordance with at least one embodiment.

FIG. 5 illustrates a cross-sectional view of a faceplate, showing a section comprising a non-uniform distribution of orifices, in accordance with at least one embodiment.

FIG. 6 illustrates a plan view of a plenum side of a faceplate, showing azimuthal and radial distributions of orifices, in accordance with at least one embodiment.

FIG. 7 illustrates a process flow chart summarizing a method for employing a showerhead comprising a distribution of orifice sizes and entrance zone dimensions, in accordance with at least one embodiment.

### DETAILED DESCRIPTION

At least one embodiment describes a process showerhead comprising orifices that comprise entrance zones. In at least one embodiment, the entrance zones are conical portions of the orifices that extend into the orifices from the plenum side of the faceplate. In at least one embodiment, the one or more entrance zones may have one conical portion. In at least one embodiment, one or more entrance zones may comprise a compound conical section. In at least one embodiment, the compound conical section comprises a first portion and a coaxial second portion, where the first portion and the second portion are conical. In at least one embodiment, the first portion is stacked over the second portion. In at least one embodiment, the first portion may have a first included conical angle that is larger than the second included conical angle of the second portion.

In at least one embodiment, the gas flow rate through an orifice comprising a compound entrance zone may be increased by increasing the first chamfer angle of a compound entrance zone. In at least one embodiment, the second subtended angle of a compound entrance zone may be adjusted to enable a smaller first subtended angle to allow a desired gas flow rate. In at least one embodiment, the smaller first subtended angle enables a smaller aperture of the compound entrance zone. In at least one embodiment, the smaller entrance zone aperture may enable a larger packing density of orifices on a showerhead faceplate since the orifice center-to-center distance may be smaller.

In at least one embodiment, gas flow rate distribution from a showerhead may be tuned by adjusting first and second subtended angles of entrance zones of orifices.

In at least one embodiment, in the following description, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. The appearances of the phrase “in an embodiment,” “in at least one embodiment,” “in one embodiment,” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

Here, the terms “coupled” and “connected,” along with their derivatives, may be used to describe functional or structural relationships between components. These terms are not intended as synonyms for each other. Rather, in particular embodiments, the term “connected” may be used to indicate that two or more elements are in direct physical, optical, or electrical contact with each other. The term “coupled” may be used to indicate that two or more elements are in either direct or indirect (with other intervening elements between them) physical, electrical or in magnetic contact with each other, and/or that the two or more elements co-operate or interact with each other (e.g., as in a cause an effect relationship). The term “coupled” may also generally refer to direct attachment of one electronic component to another. An electric or magnetic field may couple one component to another, where the field is controlled by one component to influence the other in some manner.

Here, the terms “over,” “under,” “between,” and “on” may generally refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

Unless otherwise specified in the explicit context of their use, the terms “substantially,” “substantially equal,” “about equal,” and “approximately equal” mean that there is no more than incidental variation between two things so described. In at least one embodiment, such variation is typically no more than +/−10% of the referred value.

Here, the term “wafer” may generally refer to a disc shaped substrate comprising a semiconductor material. In at least one embodiment, a wafer diameter may range between 100 mm and 450 mm.

Here, the term “plasma enhanced chemical vapor deposition (PECVD)” may generally refer to a method of thin film deposition whereby a chemical vapor comprising film precursor molecules may undergo surface reactions, forming nucleation and a polymerized or otherwise condensed film on a wafer. In at least ne embodiment, a plasma is formed within a PECVD deposition chamber by injection of electromagnetic fields into precursor vapors to increase the chemical reactivity of the precursor species.

Here, the term “process chamber” may generally refer to a high vacuum chamber (e.g., operable to hold a pressure of 20 torr or less), component of a semiconductor fabrication tool. In at least one embodiment, process chamber may generally house the tools such as a showerhead assembly and a wafer pedestal for performing a semiconductor fabrication processes on a substrate. In at least one embodiment, substrate may be a semiconductor wafer, for example, held within the process chamber. In at least one embodiment, process performed on the substrate may be a thin film deposition, for example, performed as a physical deposition process such as a metal film evaporation process, a sputtering process, etc. In at least one embodiment, other thin film fabrication processes include chemical vapor deposition (CVD) processes, atomic layer deposition (ALD) processes, PECVD deposition processes, etch processes, such as a reactive ion etch (RIE), or plasma cleaning processes. In at least one embodiment, a process chamber may comprise at least one wafer processing station into which the substrate is transferred for processing.

Here, the term “plasma chamber” may generally refer to a process chamber that is operable to support plasmas for enhancing some processes.

Here, the term “wafer pedestal” may generally refer to a platform on which a wafer may be mounted and clamped for processing within a process chamber.

Here, the term “showerhead assembly” may generally refer to a process gas distribution manifold. In at least one embodiment, a showerhead assembly comprises a faceplate that comprises a plurality of orifices from which process gases issue into the process chamber. In at least one embodiment, a showerhead assembly may be a component of a wafer processing station. In at least one embodiment, a showerhead assembly may be employed to distribute process gasses into processing chambers for atomic layer deposition processes (ALD), plasma-enhanced atomic layer deposition (PEALD), chemical vapor deposition (CVD) processes, plasma-enhanced thin film deposition (e.g., PECVD), as well as for plasma etching (e.g., RIE) and plasma cleaning processes. Herein, the term “showerhead” may be used interchangeably with the term “showerhead assembly”.

Here, the term “plenum” may generally refer to a cavity within the showerhead body that is in fluidic communication with a plurality of orifices extending through the faceplate of the showerhead. In at least one embodiment, process gases may flow into the plenum, where they may diffuse across the plenum and flow into the plurality of orifices.

Here, the term “faceplate” may generally refer to a perforated surface located at the bottom of the showerhead, facing the wafer. In at least one embodiment, process gases are distributed into a deposition chamber or an etching chamber through the plurality of orifices.

Here, the term “central region” may generally refer to a center portion of a faceplate of a showerhead.

Here, the term “peripheral region” may generally refer to a periphery of the faceplate. The peripheral region may be adjacent to the central region or distanced from it by an intermediate region.

Here, the term “process gas feed” may generally refer to a source of process gas that is external to a process chamber. In at least one embodiment, the process gas feed may comprise gas transfer lines that are coupled to the showerhead within the process chamber.

Here, the term “process gas distribution pattern” may generally refer to a two-dimensional gas flow rate pattern of a showerhead. In at least one embodiment, the process gas distribution pattern may be determined by the orifice distribution pattern on a showerhead faceplate.

Here, the term “radial distribution” may generally refer to a distribution of objects along a radius of a circular or cylindrical object. In at least one embodiment, radial distribution may be associated with a radially symmetric body, such as a circular faceplate or a wafer. In at least one embodiment, radial distribution may be azimuthally symmetric on the circular or cylindrical object.

Here, the term “azimuthal distribution” may generally refer to an angular distribution of objects around a circular form, such as a circle or cylinder cross section.

Here, the term “uniform” may generally refer to a radial or azimuthal distribution that comprises identical objects or sets of objects distributed radially or azimuthally, respectively, such as a uniform azimuthal distribution.

Here, the term “non-uniform” may generally refer to a radial or azimuthal distribution that comprises non-identical objects or sets of objects distributed radially or azimuthally, such as a non-uniform azimuthal distribution.

Here, the term “non-uniform azimuthal distribution” may generally refer to an azimuthal distribution of objects that is not symmetrical.

Here, the term “orifice” may generally refer to an opening extending through the faceplate. In at least one embodiment, an orifice enables process gases to flow into the process chamber from the plenum of the showerhead.

Here, the term “entrance zone” may generally refer to a chamfer at the upsteam entrance to an orifice. In at least one embodiment, an entrance zone may be a conical bore countersunk into the orifice from the upstream side of the faceplate. In at least one embodiment, an entrance zone may be conical. In at least one embodiment, an entrance zone is a form of a nozzle.

Here, the term “compound bore” may generally refer to a countersunk bore comprising a coaxial stack of conical bores, each bore having a different subtended angle. In at least one embodiment, a compound bore may have a first subtended angle and a second subtended angle, where the first subtended angle is larger than the second subtended angle.

Here, the term “sidewall” may generally refer to the sidewall of the conical bore of the entrance zone. In at least one embodiment, a compound bore may have a first sidewall subtending the first subtended angle, and a second sidewall subtending the second subtended angle.

Here, the term “subtended angle” may generally refer to the angle subtended by the sidewall of a countersink bore of an entrance zone. In at least one embodiment, the countersink bore referred to in this disclosure is conical. In at least one embodiment, a subtended angle is a cone angle of the entrance zone.

Here, the term “aperture” may generally refer to the opening to the entrance zone of an orifice. In at least one embodiment, an aperture may be on the upstream (plenum) side of the faceplate. In at least one embodiment, an aperture may coincide with the major diameter of the entrance zone.

Here, the term “major diameter” may generally refer to the larger diameter of a truncated cone. In at least one embodiment, a major diameter of an entrance zone is an aperture, as defined above.

Here, the term “throat” may generally refer to a straight portion of an orifice as defined in this disclosure. In at least one embodiment, the orifice may comprise a conical or compound entrance zone, a throat, and an exit nozzle. The throat may have a length that is the depth of the nozzles subtracted from the thickness of the faceplate

Here, the term “minor diameter” may generally refer to the smaller diameter of a truncated cone. In at least one embodiment, the minor diameter of the entrance zone is the diameter of the throat.

Here, the term “length” may generally refer to the length of the throat of the orifice.

Here, the term “depth” may generally refer to the distance below the upstream side of a faceplate the entrance zone extends. In at least one embodiment, depth may also refer to the distance from the downstream side of the faceplate the exit nozzle extends.

Here, the term “upstream side” may generally refer to the plenum side of a showerhead faceplate. In at least one embodiment, an upstream side of a faceplate is a side from which process gases enter orifices within faceplate from plenum of showerhead.

Here, the term “downstream side” may generally refer to a chamber side of a showerhead faceplate. In at least one embodiment, an upstream side is opposite of a downstream side (e.g., a faceplate may have an upstream side and an opposing downstream side). In at least one embodiment, a downstream side of a faceplate is a side from which process gases issue for a plurality of orifices within faceplate into a process chamber.

Here, the term “film” may generally refer to a thin layer of solid material on a substrate. In at least one embodiment, the film may be intentionally deposited or grown by number of processes, such as atomic layer deposition, plasma-enhanced atomic layer deposition, chemical vapor deposition and plasma-enhanced chemical vapor deposition.

Here, the term “substrate” may generally refer to an object comprising a surface on which a film may be deposited. In at least one embodiment, a substrate may be a wafer.

Here, the term “film deposition pattern” may generally refer to a pattern of film thickness profile associated with a particular showerhead and process recipe. In at least one embodiment, a film deposition pattern may result from a fluid dynamical process distribution pattern of process gases entering a chamber that is engineered into the showerhead, or by a pattern of plasma formation that may be engineered into the showerhead or may result from buildup of dielectric films on a surface of showerhead faceplate.

Here, the term “film layer” may generally refer to a thin film comprising one or more layers that are deposited in one process cycle. In at least one embodiment, a thin film may be deposited in one process cycle or in multiple process cycles. In at least one embodiment, a first film layer may be deposited on a wafer in a first process cycle. In at least one embodiment, a second film layer may be deposited in a second process cycle. In at least one embodiment, a first process cycle may be performed at a first wafer processing station. In at least one embodiment, a second process cycle may be performed at the same wafer processing station or at a different wafer processing station. In at least one embodiment, first film layer may comprise a first material, whereas the second film layer may comprise a first material and/or a second material.

Here, the term “thickness profile” may generally refer to a measured cross-sectional thickness of a section of a deposited film. In at least one embodiment, a film thickness profile may be measured over a film covering a wafer may be generated by profilometric measurement of film thickness across a radial distance such as a diameter of a film.

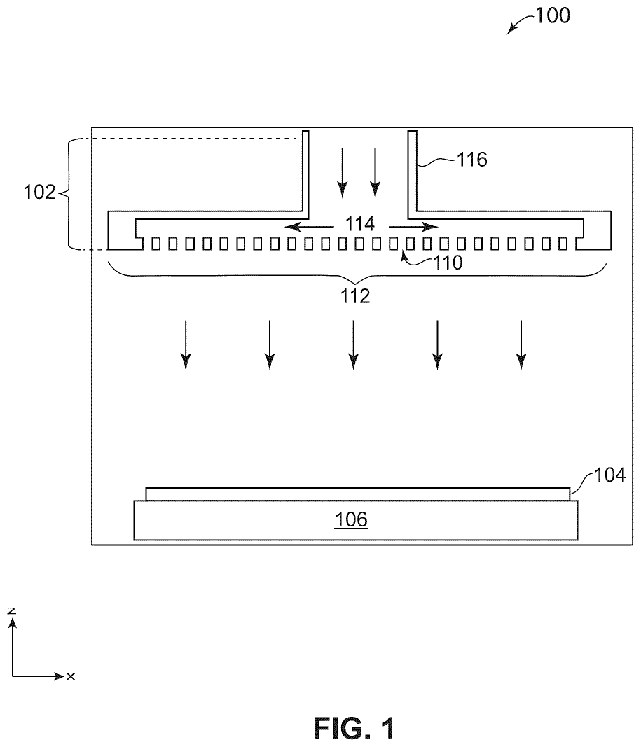

FIG. 1 illustrates a cross-sectional view of process chamber 100, in accordance with at least one embodiment. In at least one embodiment, in the cross-sectional view, process chamber may be oriented such that the z-axis is aligned along the vertical. It is to be understood by persons skilled in the art that references to “above” and “below” have the normal meanings, as noted herein. For example, “above” and “below” refer to relative vertical positions of a first object and a second object above a reference plane. For example, the reference plane may be a floor of a room in which the objects are located. Process chamber 100 is normally oriented as shown in FIG. 1, in accordance with at least one embodiment.

In at least one embodiment, process chamber 100 comprises a vacuum chamber in which thin film and other processes may be performed on a substrate. In at least one embodiment, process chamber 100 may be a component of a semiconductor integrated circuit fabrication tool. For example, process chamber 100 may be a deposition chamber, in which deposition processes such as chemical vapor deposition (CVD), atomic layer deposition (ALD), plasma-enhanced atomic layer deposition (PEALD), plasma-enhanced chemical vapor deposition (PECVD), physical deposition processes such as evaporation, sputtering and the like may be performed. In at least one embodiment, process chamber 100 may also be employed for dry etching processes, such as reactive ion etching (RIE) or plasma cleaning processes.

Depositions such as PECVD may be performed under moderate to high vacuum (e.g., less than 20 torr), in at least one embodiment. In at least one embodiment, process chamber 100 comprises a PECVD chamber. In at least one embodiment, process chamber 100 comprises gas distribution showerhead 102 (hereinafter, showerhead 102) located directed above wafer 104. In at least one embodiment, wafer 104 has a circular disk form factor, which, for example, may have a diameter ranging between 100 mm and 450 mm. In at least one embodiment, wafer 104 comprises a semiconductor material, such as silicon, germanium, gallium arsenide, indium phosphide, cadmium telluride, and the like. In at least one embodiment, wafer 104 comprises a dielectric material such as silicon nitride, silicon carbide, silicon oxide (e.g., fused silica, borosilicate glass, float glass), aluminum nitride, aluminum oxide, and the like. While the method disclosed herein is directed to semiconductor device fabrication, such as silicon-based integrated circuits, it may be understood that the method may also be readily applied to fabrication of other types of devices. In at least one embodiment, wafer 104 may represent any substrate suitable for processing by the disclosed method. In at least one embodiment, wafer 104 may be a liquid crystal display panel substrate. Such a substrate may have a rectangular form factor. In at least one embodiment, showerhead 102 may have a rectangular form factor of approximately the same dimensions as the rectangular substrate.

In at least one embodiment, showerhead 102 may have a cylindrical form factor. In at least one embodiment, showerhead 102 may have a rectangular geometry. In at least one embodiment, showerhead 102 may have a lateral dimension (e.g., a diameter or width) that is substantially the same as wafer 104. In at least one embodiment, showerhead 102 may have at least one lateral dimension that is substantially greater than the lateral dimensions of wafer 104. In at least one embodiment, showerhead 102 may have a cylindrical form factor. In at least one embodiment, diameter of showerhead 102 may be up to 50% larger than the diameter of wafer 104, in accordance with at least one embodiment.

In at least one embodiment, showerhead 102 has a cylindrical form factor. A cross-sectional view is taken across a diameter of showerhead 102. In at least one embodiment, showerhead 102 may be radially and azimuthally symmetrical or may have both radial and azimuthal structural variations. In at least one embodiment, wafer 104 is a substrate on which thin film depositions may be performed. In at least one embodiment, wafer 104 may be mounted and clamped on wafer pedestal 106. In at least one embodiment, wafer pedestal 106 may comprise a vacuum clamping or an electrostatic clamping feature to secure wafer 104. In at least one embodiment, wafer pedestal 106 may provide mechanical support for wafer 104 and electrically stabilize wafer 104 in the presence of a plasma during plasma enhanced processes, such as PECVD or RIE. In at least one embodiment, wafer pedestal 106 may be electrically grounded. In at least one embodiment, wafer pedestal 106 may be coupled to a source of electric bias. In at least one embodiment, the electric bias source may be a radio frequency (RF) or direct current (DC) voltage or power generator. In at least one embodiment, an RF generator may generate a periodic voltage waveform at frequencies of 13.56 MHz (megahertz) or greater frequencies.

In at least one embodiment, showerhead 102 comprises faceplate 112. In at least one embodiment, faceplate 112 comprises a plurality of orifices 110 radially and azimuthally distributed across faceplate 112. In at least one embodiment, plurality of orifices 110 are in fluidic communication with plenum 114, which may be coupled to conduit 116. In at least one embodiment, conduit 116 may introduce process gases into plenum 114 from one or more gas and precursor vapor sources exterior to process chamber 100. In at least one embodiment, process gases may diffuse within plenum 114 to reach and exit through plurality of orifices 110.

In at least one embodiment, plurality of orifices 110 may have refined structure (not shown) to optimize nozzle fluid dynamical characteristics for process gases exiting into process chamber through plurality of orifices 110. In at least one embodiment, plenum 114 may be dimensioned to have minimal pressure drop across the diameter of faceplate 112. In at least one embodiment, process gases diffusing across plenum 114 from the center to the periphery may have a very small radial pressure gradient so that the flow rate of process gas through all plurality of orifices 110 may be substantially uniform. In at least one embodiment, a substantial pressure gradient may be present within plenum 114.

In at least one embodiment, spatial distribution of the flow rate of process gases issuing from showerhead 102 may directly influence the three-dimensional thickness profile of a film grown on wafer 104. In at least one embodiment, a substantially uniform spatial distribution of flow rates of process gases issuing from plurality of orifices 110 may support a substantially uniform film thickness profile. In at least one embodiment, uniform spatial concentration distribution of ionized species within a plasma generated within the space between showerhead 102 and wafer 104 may enable growth of a PECVD film on wafer 104 having a low non-uniformity (% NU) figure of merit. In at least one embodiment, % NU may be determined in relative terms as a percentage non-uniformity by surface metrology, such as profilometry or ellipsometry. In at least one embodiment, a substantially non-uniform film thickness profile may be desired. In at least one embodiment, film thickness profile may be characterized by % NU. In at least one embodiment, a % NU of 1% or greater may characterize a substantially non-uniform film thickness profile. In at least one embodiment, showerhead 102 may be engineered to produce such a non-uniform film thickness profile.

In at least one embodiment, plenum 114 may be dimensioned to produce a controlled radial or azimuthal pressure distribution across the diameter of faceplate 112. In at least one embodiment, plenum 114 may be radially tapered to reduce flow to the periphery, concentrating flow through the central portion of showerhead 102. In at least one embodiment, conduit 116 may be displaced toward the periphery to introduce gases in the peripheral portion of plenum 114, enhancing flow through plurality of orifices 110 located near the periphery, at the expense of plurality of orifices 110 that are centrally located orifices.

In at least one embodiment, plurality of orifices 110 may be modified to achieve similar flow distributions. In at least one embodiment, plurality of orifices 110 that are peripherally located may have larger or smaller diameters than plurality of orifices 110 that are centrally located, for example to concentrate or limit gas flow over the peripheral portion of wafer 104. In at least one embodiment, plurality of orifices 110 that are centrally located may have larger diameters than plurality of orifices 110 located in peripheral portion of showerhead 102 to concentrate gas flow over central portion of wafer 104.

In at least one embodiment, an overall distribution of process gas flow from plurality of orifices 110 may be radially and/or azimuthally non-uniform. In at least one embodiment, non-uniform distribution of orifices may enable a specific distribution of deposition precursors over a wafer, for example, for grow a thin film having a non-uniform thickness profile.

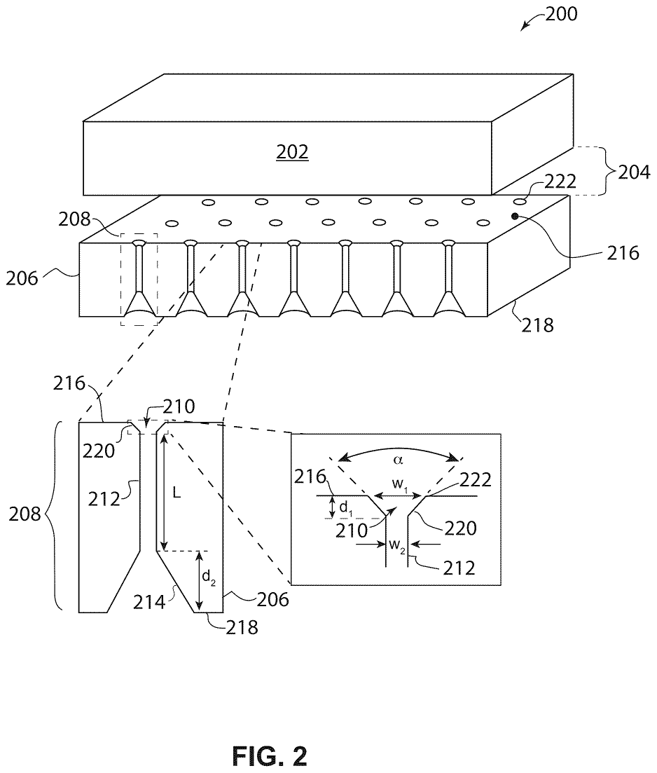

FIG. 2 illustrates a cut-away view of showerhead assembly 200, in accordance with at least one embodiment. In at least one embodiment, showerhead assembly 200 comprises upper wall 202, plenum 204 and faceplate 206. In at least one embodiment, faceplate 206 comprises a plurality of orifices 208. In at least one embodiment, orifices 208 are substantially identical to one another. An enlarged cross-sectional view of an orifice 208 is shown in the inset. In at least one embodiment, orifices 208 comprise entrance zone 210, throat 212, and exit nozzle 214. In at least one embodiment, entrance zone 210 is located on plenum side 216 (e.g., upstream side) of faceplate 206. In at least one embodiment, exit nozzle 214 is located on chamber side 218 (e.g., downstream side) of faceplate 206. In at least one embodiment, entrance zone 210 and exit nozzle 214 have conical shapes. In at least one embodiment, entrance zone 210 is an entrance nozzle. In at least one embodiment, entrance zone 210 has a subtended angle a of the conical portion of entrance zone 210. In at least one embodiment, subtended angle a may be measured as the twice the countersink chamfer angle of sidewall 220. In at least one embodiment, sidewall 220 is a conical sidewall. In at least one embodiment, subtended angle a may range between 10 degrees and 150 degrees. In at least one embodiment, sidewall 220 extends to a depth d₁ below aperture 222 on plenum side 216 of faceplate 206. In at least one embodiment, depth d₁ extends between aperture 222 and throat 212. In at least one embodiment, depth d₁ depends upon subtended angle a, and major diameter w₁ of entrance zone 210. In at least one embodiment, diameter w₂ is the minor diameter of entrance zone 210. In at least one embodiment, throat 212 has a cylindrical geometry, where diameter w₂ is a diameter of throat 212.

In at least one embodiment, subtended angle a and major diameter w₁ of entrance zone 210 may be adjusted to optimize flow rate of gases through orifice 208. In at least one embodiment, diameter w₂ of throat 212 may also be adjusted in conjunction with subtended angle a and major diameter w₁. In at least one embodiment, length L of throat 212 may be optimized by adjustment of depth d₁ of entrance zone 210 and/or depth d₂ of exit nozzle 214. In at least one embodiment, adjustment of gas flow rate through orifices 208 may be performed by optimization of parameters w₁, d₁, w₂, L and d₂. In at least one embodiment, banks of orifices 208 on faceplate 206 may be engineered for gas flow rates. In at least one embodiment, dimensions, and nozzle geometries of orifices 208 within concentric bands on a circular faceplate may be engineered to introduce process gases into a process chamber at desired gas flow rates. In at least one embodiment, gas flow rates may increase or decrease across a radius on faceplate 206 having a circular geometry. In at least one embodiment, radial distribution of orifice size and nozzle geometries may be azimuthally uniform or non-uniform.

In at least one embodiment, orifices 208 may have radially and azimuthally uniform distribution across faceplate 206. In at least one embodiment, process gases comprising film precursors for a PECVD deposition process, passing through orifices 208 may flow uniformly over a wafer positioned below showerhead assembly 200. In at least one embodiment, a film grown on the wafer by this process may have a radially and azimuthally uniform film thickness profile due to the uniformity of gas flow rates across faceplate 206.

In at least one embodiment, gas flow rates through an orifice may increase as subtended angle a {e.g. cone angle) is increased and/or major diameter w₁ is increased for a fixed minor diameter w₂. In at least one embodiment, increase of subtended angle a of entrance zone 210 increases the ability of gases to enter throat 212. In at least one embodiment, flow rates of gases issuing from orifices 208 are sensitive to changes of major diameter w₁ for relatively large subtended angles a. In at least one embodiment, subtended angle a may be greater than 45 degrees (e.g., a 22.5-degree countersink chamfer to form entrance zone 210).

In at least one embodiment, for constant a, increasing major diameter w₁ may entail increase of countersink depth d₁ of entrance zone 210. In at least one embodiment, length L of throat 212 may decrease with increasing d₁. In at least one embodiment, decreasing of length L may also result from increasing depth d₂ of exit nozzle 214. In at least one embodiment, decrease of length L of throat 212 may enhance gas flow rate through orifices 208 by decreasing mass transfer resistance.

In at least one embodiment, increasing subtended angle a for a constant w₁ may slightly increase length L of throat 212 as the countersink depth (e.g., depth d₁) becomes shallower. In at least one embodiment, gas flow rate may increase in a non-linear fashion with increasing subtended angle a for a constant w₁ and w₂. In at least one embodiment, sensitivity of flow rate to subtended angle increases with increasing major diameter w₁. In at least one embodiment, orifices 208 may be radially distributed across faceplate 206 (having a circular geometry) by incrementing major diameter w₁ of entrance zone 210 with radial distance from a center point on faceplate 206. In at least one embodiment, the radial distribution may azimuthally uniform or non-uniform. In at least one embodiment, a non-uniform azimuthal distribution of orifices 208 having radially incrementing major diameters w₁ may be symmetric about a center of faceplate 206. In at least one embodiment, in a PECVD deposition process, it may be desired to develop an azimuthally non-uniform film thickness profile on circular wafers. To produce such a film with the desired non-uniform thickness profile, in at least one embodiment, faceplate 206 may comprise multiple orifice domains.

In at least one embodiment, orifices 208 within a first orifice domain may have a radial distribution exhibiting an increasing subtended angle a. In at least one embodiment, increasing subtended angle a may enable the flow rate of precursor gases to increase radially outward to achieve a radially increasing film thickness profile within a first region on a wafer.

In at least one embodiment, orifices 208 within a second orifice domain on faceplate 206 may have a radial distribution exhibiting a decreasing subtended angle a. In at least one embodiment, a decreasing flow rate of precursor gases over a wafer may be enabled within the second orifice domain. In at least one embodiment, a radially decreasing film thickness profile may be produced over a second region on the wafer. In at least one embodiment, the first and second regions may be azimuthally separated.

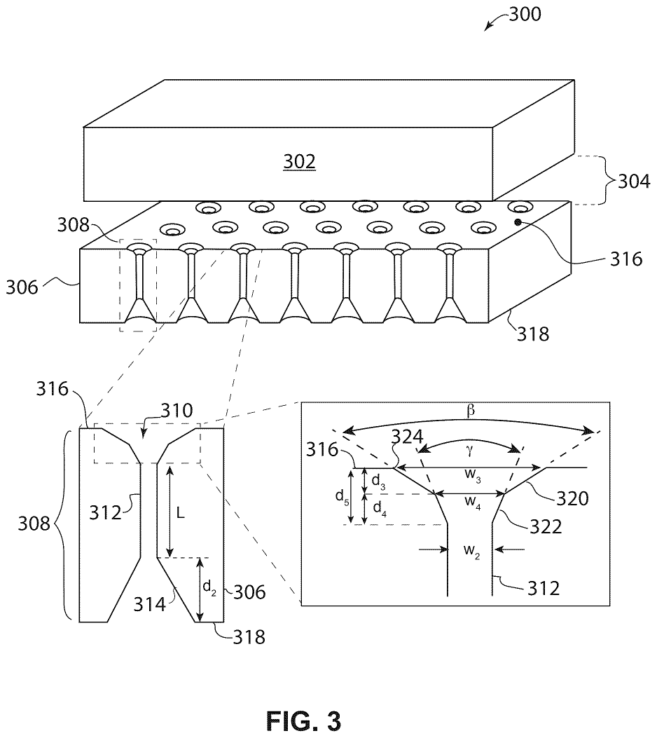

FIG. 3 illustrates a cut-away view of showerhead assembly 300, in accordance with at least one embodiment. In at least one embodiment, showerhead assembly 300 comprises backplate 302, plenum 304 and faceplate 306. In at least one embodiment, faceplate 306 comprises a plurality of orifices 308. In at least one embodiment, process gases may be introduced into plenum 304 and exit through orifices 308 into a process chamber.

In at least one embodiment, orifices 308 comprise entrance zone 310, throat 312 and exit nozzle 314. In at least one embodiment, entrance zone 310 extends below plenum side 316 (e.g., upstream side) of faceplate 306. In at least one embodiment, exit nozzle 314 extends below chamber side 318 (e.g., downstream side) of faceplate 306. In at least one embodiment, entrance zone 310 and exit nozzle 314 are interconnected by throat 312.

In at least one embodiment, entrance zone 310 is a compound nozzle, comprising a compound bore. In at least one embodiment, compound bore of entrance zone 310 comprises a stacked conical nozzle structure. In at least one embodiment, compound bore of entrance zone 310 comprises first subtended angle b and second subtended angle g. In at least one embodiment, first subtended angle b is larger than second subtended angle g, as shown in the first inset. In at least one embodiment, first subtended angle b may be measured as twice a first countersink chamfer angle. In at least one embodiment, second subtended angle g may be measured as twice a second countersink chamfer angle. In at least one embodiment, first subtended angle b may range between 10 degrees and 150 degrees. In at least one embodiment, second subtended angle g may range between 10 degrees and 120 degrees.

In at least one embodiment, first subtended angle b is subtended by first sidewall 320 of entrance zone 310, as shown in the second inset. In at least one embodiment, second subtended angle g is subtended by second sidewall 322 of entrance zone 310. In at least one embodiment, first sidewall 320 is stacked over second sidewall 322. In at least one embodiment, entrance zone 310 extends below aperture 324 on plenum side 316 of faceplate 306. In at least one embodiment, entrance zone 310 has a major diameter w₃ coinciding with aperture 324. In at least one embodiment, first sidewall 320 extends a depth d₃ from aperture 324 to second sidewall 322. In at least one embodiment, first sidewall 320 converges to a diameter w₄ at the junction between first sidewall 320 and second sidewall 322. In at least one embodiment, second sidewall 322 extends to a depth d₄ below first sidewall 320, converging to a diameter w₂ at the junction between entrance zone 310 and throat 312. In at least one embodiment, entrance zone 310 extends a total depth d₅ (e.g., d₅ is the sum of depths d₃ and d₄) below aperture 324 in plenum side 316 of faceplate 306.

In at least one embodiment, entrance zone 310 has a first subtended angle b that is twice the second subtended angle g. In at least one embodiment, first subtended angle b is 120 degrees and second subtended angle g is 60 degrees. In at least one embodiment, g may be approximately midway between b and 180 degrees. In at least one embodiment, second subtended angle g enables a transition for gas flow into orifices 308 from first subtended angle b to throat 312. In at least one embodiment, transition enabled by second sidewall 322 of entrance zone 310, subtending second subtended angle g, may enable larger gas flow rate through orifices 308 than first sidewall 320 alone. In at least one embodiment, first sidewall 320 is a conical sidewall. In at least one embodiment, second sidewall 322 is a conical sidewall. In at least one embodiment, for a given gas flow rate, the presence of second subtended angle g may enable first subtended angle b and diameter w₃ of aperture 324 to be smaller than subtended angle a and aperture 222 for entrance zone 210 having sidewall 220 (see FIG. 2). In at least one embodiment, a larger density of orifices 308 in faceplate 306 may be enabled, if desired, relative to an orifice density in faceplate 206 to achieve a desired gas flow rate.

In at least one embodiment, diameter w₂ of throat 312 may also be adjusted to accommodate desired gas flow rates. In at least one embodiment, a higher gas flow rate may be achieved for smaller diameter w₂ of throat 312 relative to throat 212 for entrance zone 210 (e.g., where subtended angle a and aperture diameter w₁ of entrance zone 210 is same as subtended angle b and aperture diameter w₃ of entrance zone 310, respectively).

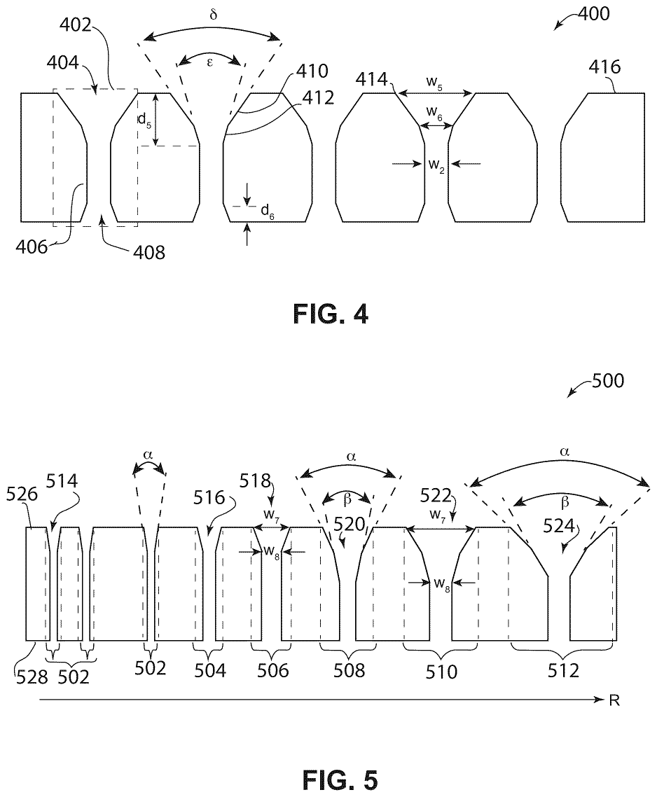

FIG. 4 illustrates a cross-sectional view of faceplate 400, showing a section of faceplate 400 comprising a uniform distribution of orifices 402, in accordance with at least one embodiment. In at least one embodiment, faceplate 400 is part of a showerhead, similar to showerhead assembly 300. In at least one embodiment, orifices 402 comprise entrance zone 404, throat 406, and exit nozzle 408. In at least one embodiment, entrance zone 404 and exit nozzle 408 are interconnected by throat 406.

In at least one embodiment, entrance zone 404 is a compound nozzle comprising subtended angle d and second subtended angle e, subtended by sidewalls 410 and 412, respectively. In at least one embodiment, subtended angles d and e are similar to first subtended angle b and second subtended angle g of entrance zone 310, respectively. In at least one embodiment, entrance zone 404 may have a major diameter w₅ that coincides with aperture 414 on plenum side 416 of faceplate 400. In at least one embodiment, entrance zone 404 extends a depth d₅ below plenum side 416 of faceplate 400. In at least one embodiment, depth d₅ may range from approximately 1% to 60% of thickness t of faceplate 400. In at least one embodiment, depth d₅ may be adjusted by adjustments of first and second subtended angles d and e, major diameter w₅, and first minor diameter w₆. In at least one embodiment, major diameter w₅ may be optimized for desired orifice densities. In at least one embodiment, major diameter w₅ may be optimized by adjustment of subtended angles d and e. In at least one embodiment, to enable a desired major diameter w₅, range of subtended angles d and e may have a dependency on diameter w₂ of throat 406.

In at least one embodiment, length L of throat 406 may be dependent on depth d₅ of entrance zone 404. In at least one embodiment, length L of throat 406 may be dependent on both depth d₅ and depth d₆ of exit nozzle 408. In at least one embodiment, depth d₆ may range from zero (e.g., absence of exit nozzle 408) to approximately 60% of thickness t of faceplate 400. In at least one embodiment, length L may be optimized to achieve a desired gas flow rate through orifices 402. In at least one embodiment, length L may be decreased by increasing d₅ and/or d₆. In at least one embodiment, shortening of length L may reduce gas flow resistance in orifices 402.

FIG. 5 illustrates a cross-sectional view of faceplate 500, showing a section of faceplate 400 comprising a non-uniform distribution of orifices 402, in accordance with at least one embodiment. In at least one embodiment, faceplate 500 is part of a showerhead, such as in showerhead assembly 300. In at least one embodiment, faceplate 500 has a circular geometry. In at least one embodiment, faceplate 500 comprises a non-uniform plurality of orifices 502, 504, 506, 508, 510, and 512 (enclosed within dashed boxes). In at least one embodiment, plurality of orifices 502-512 exhibit progressively increasing subtended angles a, major diameters w₇, and minor diameters w₈. In at least one embodiment plurality of orifices 502-512 increase in size (e.g., diameters w₇ and w₈) incrementally along a radial direction R on faceplate 500. Here, the arrow points toward the periphery of faceplate 500. In at least one embodiment, plurality of orifices 502 are distributed in multiple bands in a central region of faceplate 500. In at least one embodiment, plurality of orifices 502, 504, and 506, located in the vicinity of a central region of faceplate 500, comprise entrance zones 514, 516, and 518, respectively. In at least one embodiment, entrance zones 514, 516, and 518 are conical nozzles.

In at least one embodiment, orifices 508, 510, and 512, located in a peripheral region of faceplate 500, comprise entrance zones 520, 522 and 524, respectively. In at least one embodiment, entrance zones 520, 522, and 524 have at least two angles. In at least one embodiment, entrance zones 514-524 extend into faceplate 500 from plenum side 526 of faceplate 500. In at least one embodiment, orifices extend to chamber side 528 of faceplate 500. In at least one embodiment, orifices 502-512 do not have exit nozzles, as shown. In at least one embodiment, orifices 502-512 comprise exit nozzles (not shown). In at least one embodiment, orifices 508, 510 and 512 exhibit a progressive increase in first subtended angle a (as well as major diameter w₇ and minor diameter w₈) along radial direction R. In at least one embodiment, orifices 508, 510 and 512 also exhibit a progressive increase in second subtended angle b along radial direction R.

In at least one embodiment, larger dimensions and subtended angles of plurality of orifices 508-512 relative to plurality of orifices 502-506 may enable progressively increasing gas flow rates distributed across faceplate 500, from the central region of faceplate 500 to the periphery. In at least one embodiment, orifice dimensions and subtended angles may be decreased from the central region of faceplate 500 to the peripheral region. In at least one embodiment, a progressive decrease in orifice dimensions and subtended angles may enable a progressive decrease in gas flow rates distributed across faceplate 500. In at least one embodiment, plurality of orifices 502-512 may be distributed in a non-monotonic fashion. In at least one embodiment, plurality of orifices 512, having the largest aperture, may be positioned midway between plurality of orifices 506 and 508 having relatively smaller aperture.

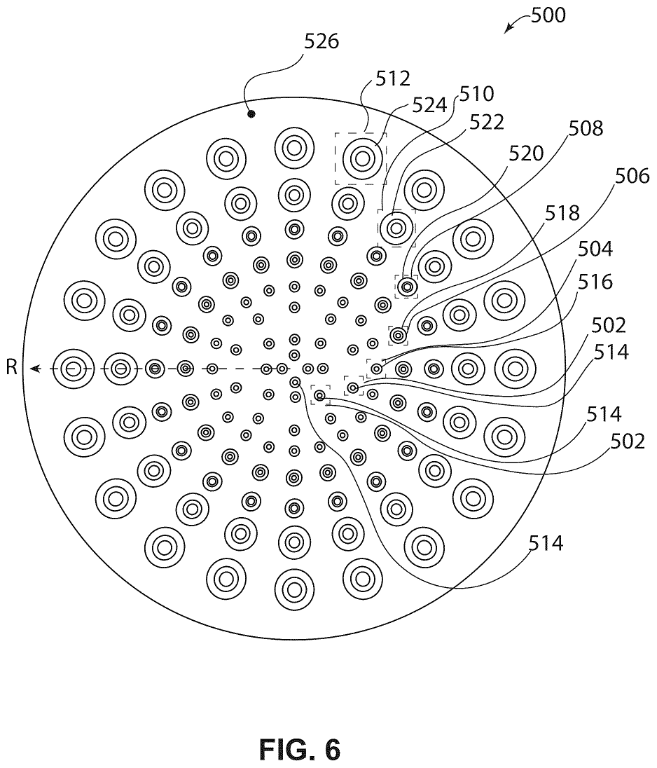

FIG. 6 illustrates a plan view of plenum side 526 of faceplate 500, showing azimuthal and radial distributions of plurality of orifices 502-524, in accordance with at least one embodiment. In FIG. 6, a plan view of entrance zones 514-524 for plurality of orifices 502-512, respectively, is shown. In at least one embodiment, plurality of orifices 502-524 are substantially uniformly distributed at all azimuths. In at least one embodiment, azimuthal distribution of plurality of orifices 502-524 may be non-uniform. In at least one embodiment, faceplate 500 may comprise two or more domains, where orifice density may be higher in one or more domains than in other domains having relatively few or no orifices. In at least one embodiment, faceplate 500 may comprise multiple domains having orifices of a particular size, nozzle structure, or throat diameter. In at least one embodiment, larger orifices may be concentrated within at least a first domain, whereas smaller orifices may be concentrated within at least a second domain.

In at least one embodiment, grouping orifices by size within azimuthally (and/or radially) distributed domains may enable azimuthally non-uniform distribution of gas flow rates across faceplate 500. In at least one embodiment, such a non-uniform distribution of orifice domains may enable a deposition or etching process to intentionally introduce non-uniformities onto a wafer or compensate for non-uniformities introduced onto the wafer by an earlier process.

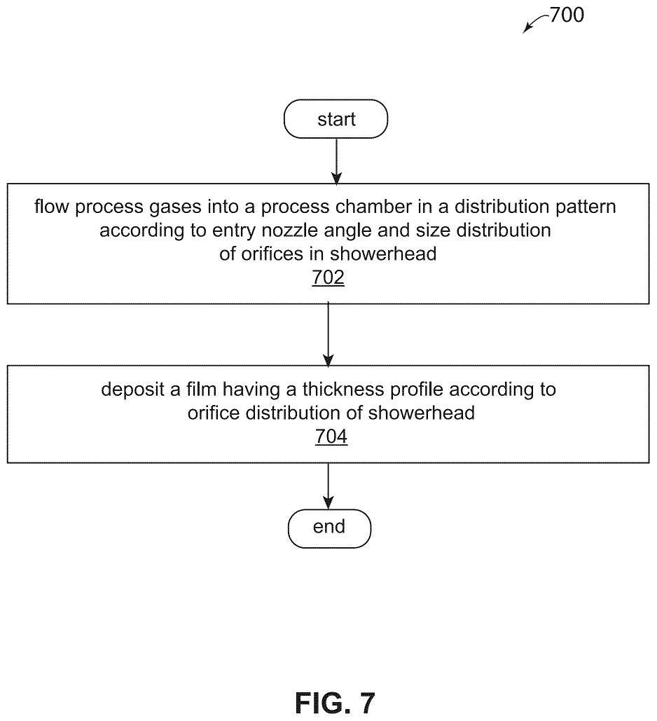

FIG. 7 illustrates process flow chart 700 summarizing a method for employing a showerhead comprising a distribution of orifice sizes and entrance zone dimensions (e.g., major diameters w₇), in accordance with at least one embodiment. In at least one embodiment, the showerhead is like showerhead 102 and showerhead in showerhead assembly 300 shown in FIGS. 1 and 3, respectively. In at least one embodiment, showerhead comprises a plenum (e.g., plenum 304) and a faceplate (e.g., any of faceplates 206, 306, 400, and 500). In at least one embodiment, a faceplate comprises a plenum side (e.g., plenum side 526). In at least one embodiment, orifices extending through the faceplate are like orifices 502-512 within faceplate 500, shown in FIGS. 5 and 6.

In at least one embodiment, at operation 702, a process gas is introduced into the plenum and begins to enter entrance zones (e.g., entrance zones 514-524) extending through the faceplate (e.g., faceplate 500) from the plenum side (e.g., plenum side 526). In at least one embodiment, flow rates of gases entering entrance zones 514-524 may increase as the first subtended angle increases. For example, orifices 512 comprise entrance zones 524 having the largest subtended angle a relative to orifices 502-510. In at least one embodiment, gas flow rates through orifices 512 may be highest among the gas flow rates through orifices 502-510.

In at least one embodiment, orifices 502 comprise entrance zones (e.g., entrance zones 514) having smaller subtended angle a relative to orifices 504-512. In at least one embodiment, gas flow rates through orifices 502 may be lowest among gas flow rates through orifices 502-510. In at least one embodiment, gas flow rates through orifices 504-510 may take on values intermediate between gas flow rates through orifices 502 and orifices 512. In at least one embodiment, orifices 502-512 may be radially and azimuthally distributed on the faceplate (e.g., faceplate 500) to achieve a desired gas flow rate distribution. In at least one embodiment, the gas flow rate distribution may be azimuthally uniform. In at least one embodiment, the gas flow rate may be azimuthally non-uniform.

In at least one embodiment, a radially increasing gas flow rate may be achieved by distributing orifices with increasing angle a along a radial direction toward the periphery of a faceplate (e.g., orifices 502-512 radially distributed in sequential order on faceplate 500). In at least one embodiment, a radially decreasing gas flow rate may be achieved by distribution orifices with decreasing angle a along a radial direction toward the periphery of a faceplate (e.g., orifices 502-512 radially distributed in anti-sequential order on faceplate 500). In at least one embodiment, second subtended angle b of entrance zones 520-524 (e.g., having at least two angles) may be adjusted to minimize angle a and major diameter (e.g., major diameter w₇), while enabling the same or greater gas flow rate. In at least one embodiment, smaller w₇ may increase orifice density on the faceplate (e.g., faceplate 500). In at least one embodiment, similar orifice distributions may be achieved for non-circular geometries, such as rectangular showerhead/faceplate geometries.

In at least one embodiment, at operation 704, gases exit orifices extending through the faceplate (e.g., orifices 502-512 on faceplate 500). In at least one embodiment, gases enter the space within a process chamber (e.g., process chamber 100, FIG. 1) between the showerhead (e.g., showerhead 102, FIG. 1) and a wafer (e.g., wafer 104, FIG. 1). In at least one embodiment, the showerhead may achieve a desired gas flow rate pattern according to the orifice distribution of the showerhead. In at least one embodiment, for a chemical vapor deposition such as a PECVD process, a plasma ion distribution may be highly influenced by the distribution of gases exiting the showerhead. In at least one embodiment, plasma ion distribution may directly influence the thickness profile of a film deposited by the process on the wafer.

The following examples are provided that illustrate the various embodiments. The examples can be combined with other examples. As such, various embodiments can be combined with other embodiments without changing the scope of the disclosure.

Example 1 is a showerhead assembly, comprising a faceplate having an upstream side and a downstream side, wherein the downstream side is opposite to the upstream side and a plurality of orifices extending through the faceplate, wherein at least one orifice of the plurality of orifices comprises an entrance zone on the upstream side of the faceplate, wherein the entrance zone comprises a compound bore, wherein the compound bore has at least a first sidewall stacked over a second sidewall, and wherein the first sidewall has a first subtended angle that is larger than a second subtended angle of the second sidewall.

Example 2 is a showerhead assembly according to any example herein, in particular example 1, wherein the entrance zone comprises an aperture on the upstream side of the faceplate, wherein the aperture has a diameter that is a major diameter of the entrance zone.

Example 3 is a showerhead assembly according to any example herein, in particular example 1, wherein the first subtended angle ranges between 90 degrees and 150 degrees.

Example 4 is a showerhead assembly according to any example herein, in particular example 1, wherein the second subtended angle ranges between 10 degrees and 90 degrees.

Example 5 is a showerhead assembly according to any example herein, in particular example 1, wherein the entrance zone extends a first depth below the upstream side of the faceplate.

Example 6 is a showerhead assembly according to any example herein, in particular example 5, wherein the first sidewall extends a second depth below the upstream side of the faceplate.

Example 7 is a showerhead assembly according to any example herein, in particular example 6, wherein the second sidewall extends a third depth below the upstream side of the faceplate.

Example 8 is a showerhead assembly according to any example herein, in particular example 7, wherein the first depth is approximately a sum of the second depth and the third depth.

Example 9 is a showerhead assembly according to any example herein, in particular example 8, wherein the at least one orifice comprises a throat.

Example 10 is a showerhead assembly according to any example herein, in particular example 9, wherein the throat has a length that is at least approximately a difference between a thickness of the faceplate and the first depth.

Example 11 is a showerhead assembly according to any example herein, in particular example 10, wherein the at least one orifice comprises an exit nozzle on the downstream side of the faceplate, wherein the exit nozzle has a fourth depth extending into the faceplate from the downstream side, and wherein the length of the throat is equal to the difference between the thickness of faceplate and approximately a sum of the first depth and the fourth depth.

Example 12 is a showerhead assembly according to any example herein, in particular example 9, wherein the throat has a diameter that is substantially equal to a minor diameter of the entrance zone.

Example 13 is a showerhead assembly according to any example herein, in particular example 2, wherein the major diameter of the at least one orifice increases radially from a central region of the faceplate to a peripheral region of the faceplate.

Example 14 is a showerhead assembly according to any example herein, in particular example 2, wherein the major diameter of the at least one orifice decreases radially from a central region of the faceplate to a peripheral region of the faceplate.

Example 15 is a showerhead assembly according to any example herein, in particular example 2, wherein the major diameter of the at least one orifice has a uniform azimuthal distribution on the faceplate.

Example 16 is a showerhead assembly according to any example herein, in particular example 2, wherein the major diameter of the at least one orifice has a non-uniform azimuthal distribution on the faceplate.

Example 17 is a system, comprising a process chamber, a showerhead within the process chamber; and a wafer pedestal below the showerhead, wherein the showerhead comprises a faceplate having an upstream side and an opposing downstream side; and a plurality of orifices extending through the faceplate, wherein at least one orifice of the plurality of orifices comprises an entrance zone on the upstream side of the faceplate, wherein the entrance zone comprises a compound bore, wherein the compound bore has at least a first sidewall stacked over a second sidewall, and wherein the first sidewall has a first subtended angle that is larger than a second subtended angle of the second sidewall.

Example 18 is a system according to any example herein, in particular example 17, wherein the showerhead is coupled to a process gas feed.

Example 19 is a system according to any example herein, in particular example 17, wherein the process chamber is a plasma chamber.

Example 20 is a method, comprising flowing a process gas into a process chamber through a showerhead, wherein the showerhead comprises a faceplate having an upstream side and an opposing downstream side; and a plurality of orifices extending through the faceplate, wherein at least one orifice of the plurality of orifices comprises an entrance zone on the upstream side of the faceplate, wherein the entrance zone comprises a compound bore, wherein the compound bore has at least a first sidewall stacked over a second sidewall, and wherein the first sidewall has a first subtended angle that is larger than a second subtended angle of the second sidewall; and depositing a film over a substrate, wherein the film has a thickness profile according to a distribution of the plurality of orifices.

Example 21 is a method according to any example herein, in particular example 20, wherein depositing the film over the substrate comprises growing the film on the substrate, and wherein the thickness profile of the film is determined by a process gas distribution pattern of the plurality of orifices.

Besides what is described herein, various modifications may be made to the disclosed embodiments and implementations thereof without departing from their scope. Therefore, illustrations of embodiments herein should be construed as examples only, and not restrictive to the scope of the present disclosure. The scope of the disclosure should be measured solely by reference to the claims that follow.

We claim:

1. A showerhead assembly, comprising:
a faceplate having an upstream side and a downstream side, wherein the downstream side is opposite to the upstream side and
a plurality of orifices extending through the faceplate, wherein at least one orifice of the plurality of orifices comprises an entrance zone on the upstream side of the faceplate, wherein the entrance zone comprises a compound bore, wherein the compound bore has at least a first sidewall stacked over a second sidewall, and wherein the first sidewall has a first subtended angle that is larger than a second subtended angle of the second sidewall.

2. The showerhead assembly of claim 1, wherein the entrance zone comprises an aperture on the upstream side of the faceplate, wherein the aperture has a diameter that is a major diameter of the entrance zone.

3. The showerhead assembly of claim 1, wherein the first subtended angle ranges between 90 degrees and 150 degrees.

4. The showerhead assembly of claim 1, wherein the second subtended angle ranges between 10 degrees and 90 degrees.

5. The showerhead assembly of claim 1, wherein the entrance zone extends a first depth below the upstream side of the faceplate.

6. The showerhead assembly of claim 5, wherein the first sidewall extends a second depth below the upstream side of the faceplate.

7. The showerhead assembly of claim 6, wherein the second sidewall extends a third depth below the upstream side of the faceplate.

8. The showerhead assembly of claim 7, wherein the first depth is approximately a sum of the second depth and the third depth.

9. The showerhead assembly of claim 8, wherein the at least one orifice comprises a throat.

10. The showerhead assembly of claim 9, wherein the throat has a length that is at least approximately a difference between a thickness of the faceplate and the first depth.

11. The showerhead assembly of claim 10, wherein the at least one orifice comprises an exit nozzle on the downstream side of the faceplate, wherein the exit nozzle has a fourth depth extending into the faceplate from the downstream side, and wherein the length of the throat is equal to the difference between the thickness of faceplate and approximately a sum of the first depth and the fourth depth.

12. The showerhead assembly of claim 9, wherein the throat has a diameter that is substantially equal to a minor diameter of the entrance zone.

13. The showerhead assembly of claim 2, wherein the major diameter of the at least one orifice increases radially from a central region of the faceplate to a peripheral region of the faceplate.

14. The showerhead assembly of claim 2, wherein the major diameter of the at least one orifice decreases radially from a central region of the faceplate to a peripheral region of the faceplate.

15. The showerhead assembly of claim 2, wherein the major diameter of the at least one orifice has a uniform azimuthal distribution on the faceplate.

16. The showerhead assembly of claim 2, wherein the major diameter of the at least one orifice has a non-uniform azimuthal distribution on the faceplate.

17. A system, comprising:
a process chamber;
a showerhead within the process chamber; and
a wafer pedestal below the showerhead, wherein the showerhead comprises:
a faceplate having an upstream side and an opposing downstream side; and
a plurality of orifices extending through the faceplate, wherein at least one orifice of the plurality of orifices comprises an entrance zone on the upstream side of the faceplate, wherein the entrance zone comprises a compound bore, wherein the compound bore has at least a first sidewall stacked over a second sidewall, and wherein the first sidewall has a first subtended angle that is larger than a second subtended angle of the second sidewall.

18. The system of claim 17, wherein the showerhead is coupled to a process gas feed.

19. The system of claim 17, wherein the process chamber is a plasma chamber.

20. A method, comprising:
flowing a process gas into a process chamber through a showerhead, wherein the showerhead comprises:
a faceplate having an upstream side and an opposing downstream side; and
a plurality of orifices extending through the faceplate, wherein at least one orifice of the plurality of orifices comprises an entrance zone on the upstream side of the faceplate, wherein the entrance zone comprises a compound bore, wherein the compound bore has at least a first sidewall stacked over a second sidewall, and wherein the first sidewall has a first subtended angle that is larger than a second subtended angle of the second sidewall; and
depositing a film over a substrate, wherein the film has a thickness profile according to a distribution of the plurality of orifices.

21. The method of claim 20, wherein depositing the film over the substrate comprises growing the film on the substrate, and wherein the thickness profile of the film is determined by a process gas distribution pattern of the plurality of orifices.
